(19) United States
(12) Patent Application Publication
(10) Pub. No.: US 2014/0357056 A1
(43) Pub. Date: Dec. 4, 2014

(54) METHOD OF FORMING SIGMA-SHAPED TRENCH

(71) Applicant: Shanghai Huali Microelectronics Corporation, Shanghai (CN)

(72) Inventors: Quanbo Li, Shanghai (CN); Yu Zhang, Shanghai (CN); Jun Huang, Shanghai (CN); Shu Koon Pang, Shanghai (CN)

(73) Assignee: Shanghai Huali Microelectronics Corporation, Shanghai (CN)

(21) Appl. No.: 14/092,235

(22) Filed: Nov. 27, 2013

(30) Foreign Application Priority Data
Jun. 3, 2013 (CN) 201310217267.1

(51) Int. Cl. H01L 21/3065; H01L 21/02

(52) U.S. Cl. CPC H01L 21/3065; H01L 21/02381; H01L 21/02532; H01L 21/02658
USPC 438/478; 438/719

(57) ABSTRACT

A method of forming a Σ-shaped trench is disclosed. The method includes: providing a silicon substrate; and performing a plasma etching process to form a Σ-shaped trench in the silicon substrate. The plasma etching process includes: etching the silicon substrate using a first plasma etching gas including a sulphur-containing fluoride; and etching the silicon substrate using a second plasma etching gas including a sulphur-containing fluoride and a polymer gas. A method of forming a semiconductor device is also disclosed.

### CROSS-REFERENCES TO RELATED APPLICATIONS

This application claims the priority of Chinese patent application number 201310217267.1, filed on Jun. 3, 2013, the entire contents of which are incorporated herein by reference.

### TECHNICAL FIELD

The present invention relates generally to the semiconductor technology, and more particularly, to forming sigma (Σ)-shaped trenches.

### BACKGROUND

With the advancing of semiconductor manufacturing technology, critical dimensions of semiconductor devices shrink increasingly. For example, when to fabricate a P-Type metal oxide semiconductor (PMOS) transistor with a critical dimension of 40 nm or below, the employment of the embedded silicon-germanium (SiGe) epitaxial growth process is needed for increasing a drive current of the PMOS transistor. Before the SiGe epitaxial growth process, a trench forming process is needed to form a trench in the silicon substrate. The trench typically resembles in shape either the capital U or the capital Greek letter sigma (Σ), in which, the Σ-shaped one can better increase the drive current since the outer periphery of which is closer to the conductive channel of the transistor.

FIGS. 1 to 3 show a prior art method of forming such a Σ-shaped trench, which includes: providing a silicon substrate 10 having two or more gate structures 20 formed thereon; forming a protective silicon nitride layer 30 over and to protect the gate structures 20; as shown in FIG. 2, performing a plasma etching process to form a trench 40 in the silicon substrate 10, the trench 40 having side walls each, perpendicular to, or inclined with respect to the bottom thereof; and performing a wet etching process, in which etching rate varies with crystal orientation, to thereby form the Σ-shaped trench 50, as show in FIG. 3. The horizontal width of the formed Σ-shaped trench 50 first gradually increases to a maximum value L and then gradually decreases in the direction from the top surface of the silicon substrate 10 downwards.

In the above-described method, the wet etching process determines how the horizontal width of the Σ-shaped trench 50 varies. That is, a maximum width L of the Σ-shaped trench 50 is determined by a vertical depth H (referring to FIG. 3) thereof. As a result, it is substantially impossible to further expand the maximum width L for a given depth H. This limits the process window of the method and impedes the improvement of the drive current.

### SUMMARY OF THE INVENTION

The present invention is directed to a method of forming a Σ-shaped trench to simplify the process and enable geometric variations of the Σ-shaped trench.

The present invention provides, in one aspect, a method of forming a Σ-shaped trench, which includes: providing a silicon substrate; and performing a plasma etching process to form a Σ-shaped trench in the silicon substrate. The plasma etching process includes: etching the silicon substrate using a first plasma etching gas including a sulphur-containing fluoride; and etching the silicon substrate using a second plasma etching gas including a sulphur-containing fluoride and a polymer gas.

Further, the first plasma etching gas may contain SF₆ supplied at a flow rate of 5 SCCM to 20 SCCM and the silicon substrate is etched using the first plasma etching gas in an etching chamber under a pressure of 40 mTorr to 60 mTorr, at an etching power of 200 W to 300 W and at a bias power of 0 W for 15 seconds to 25 seconds.

Further, the second plasma etching gas may contain SF_{S} supplied at a flow rate of 5 SCCM to 10 SCCM and a polymer gas formed of HBr supplied at a flow rate of 20 SCCM to 50 SCCM and O₂ supplied at a flow rate of 2 SCCM to 10 SCCM; the silicon substrate may be etched using the second plasma etching gas in an etching chamber under a pressure of 5 mTorr to 10 mTorr, at an etching power of 100 W to 200 W and at a bias power of 200 W to 300 W for 10 seconds to 20 seconds.

Further, the Σ-shaped trench may have a horizontal width gradually increasing to a maximum and then gradually decreasing, from a surface of the silicon substrate downwards.

The present invention provides, in another aspect, a method of forming a semiconductor device, which includes: providing a silicon substrate having two gate structures formed thereon and forming a protective layer over the silicon substrate; performing a plasma etching process on the protective layer and the underlying silicon substrate to form a Σ-shaped trench in a portion of the silicon substrate between the two gate structures; and forming a SiGe epitaxial layer in the Σ-shaped trench; wherein the plasma etching process includes: etching the protective layer to expose a surface of the silicon substrate using a first plasma etching gas including a carbon-containing fluoride; etching the portion of the silicon substrate between the two gate structures using a second plasma etching gas including a sulphur-containing fluoride; and etching the portion of the silicon substrate between the two gate structures using a third plasma etching gas including a sulphur-containing fluoride and a polymer gas.

Further, the protective layer may be fabricated by silicon nitride and may have a thickness of 100 Å to 150 Å. Further, the first plasma etching gas may contain CF₄ supplied at a flow rate of 50 SCCM to 100 SCCM.

As indicated above, the present invention has the following advantages over the prior art.

The Σ-shaped trench is formed only by employing the plasma etching process whilst not employing the wet etching process, therefore, the wet etching process apparatuses are not needed, thus simplifying the process. Further, as plasma (dry) etching processes are better controllable than wet etching processes, the Σ-shaped trench formation process of the present invention could be more precisely controlled and result in a Σ-shaped trench having an outer periphery closer to the conductive channel of the transistor and thereby further improving a drive current thereof.

### BRIEF DESCRIPTION OF DRAWINGS

FIGS. 1 to 3 are cross-sectional views schematically illustrating a prior art method of forming a Σ-shaped trench;

FIG. 4 depicts a flowchart graphically illustrating a method of forming a semiconductor device embodying the present invention; and

FIGS. 5 to 7 are cross-sectional views schematically illustrating process steps of a method of forming a semiconductor device in accordance with one embodiment of the present invention.

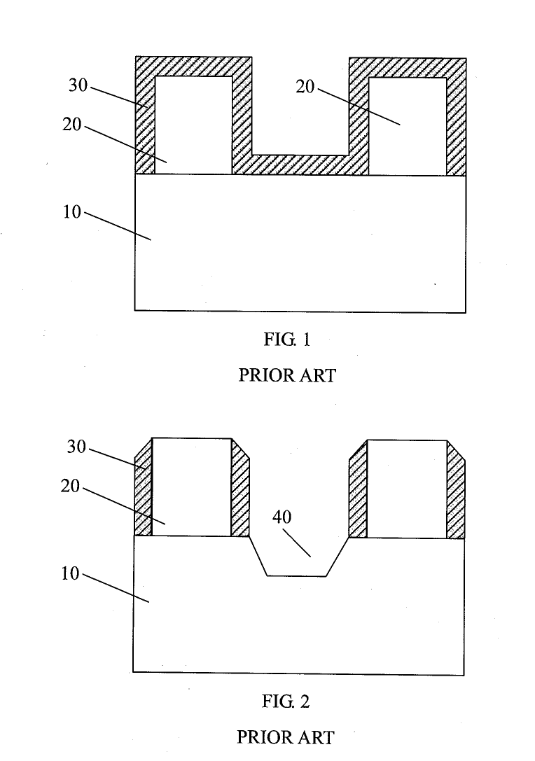

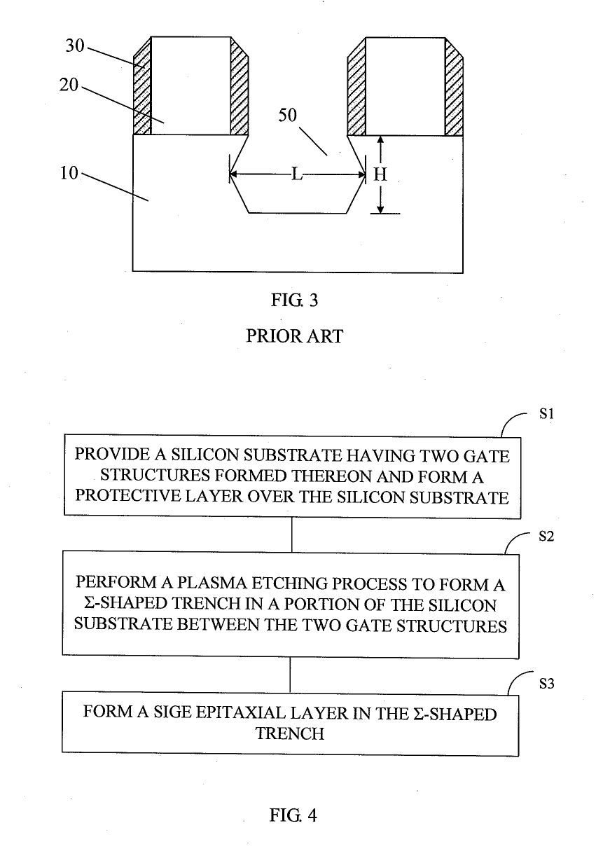

### DETAILED DESCRIPTION

The present invention provides a method of forming a sigma (Σ)-shaped trench and a method of forming a semiconductor device using the same. FIG. 4 depicts a flowchart graphically illustrating a method of forming a semiconductor device embodying the present invention.

As illustrated in FIG. 4, in a first step S1 of the method, a silicon substrate having two gate structures formed thereon is provided, and a protective layer is formed over the silicon substrate.

In a second step S2, a plasma etching process is performed to form a Σ-shaped trench in a portion of the silicon substrate between the two gate structures.

Lastly, in a third step S3, a silicon-germanium (SiGe) epitaxial layer is formed in the Σ-shaped trench.

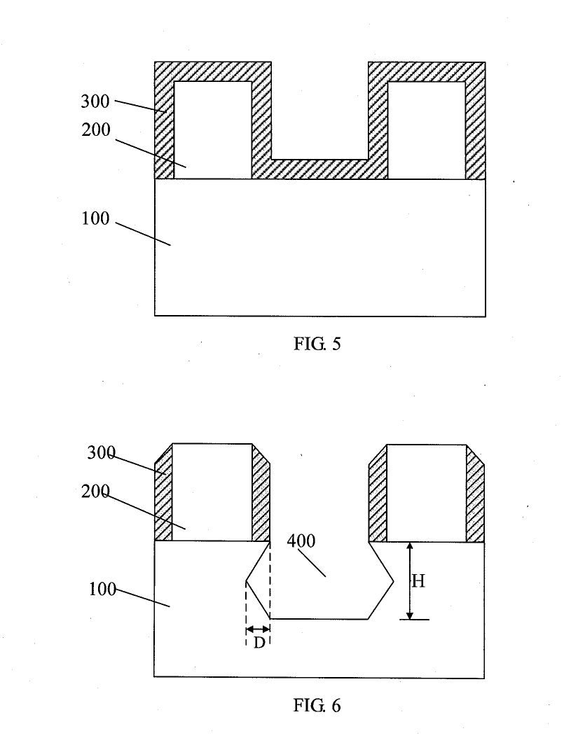

The invention is explained in greater detail below on the basis of exemplary embodiments and the figures pertaining thereto. FIGS. 5 to 7 are cross-sectional views schematically illustrating process steps for forming a semiconductor device in accordance with one exemplary embodiment of the present invention.

Referring now to FIG. 5, a silicon substrate 100 having two gate structures 200 formed thereon is first provided. A protective layer 300 is formed over the silicon substrate 100, namely covering the top and side faces of each of the gate structures 200 as well as the surface of the silicon substrate 100. The protective layer 300 is adapted to protect the gate structures 200 and may be fabricated by silicon nitride and have a thickness of 100 Å to 150 Å.

Next, referring to FIG. 6, a plasma etching process is performed to form a Σ-shaped trench 400 in the silicon substrate 100. In certain embodiments, the plasma etching process includes etching away a portion of the protective silicon nitride layer on top face of each gate structure 200 and a portion of the protective silicon nitride layer on surface of the silicon substrate 100 to expose an area for forming the Σ-shaped trench using a first plasma etching gas including a carbon-containing fluoride. The plasma etching process further includes etching a portion of the silicon substrate 100 between the gate structures 200 using a second plasma etching gas including a sulphur-containing fluoride and then further etching the portion of silicon substrate 100 between the gate structures 200 using a third plasma etching gas including a sulphur-containing fluoride and a polymer gas formed of hydrogen bromide (HBr) and oxygen (O₂).

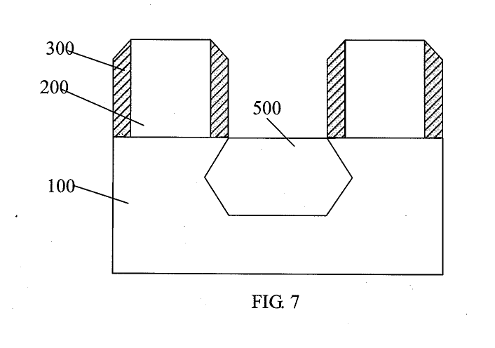

Lastly, referring to FIG. 7, a silicon-germanium (SiGe) epitaxial layer 500 is formed in the Σ-shaped trench 400 by, for example, an embedded SiGe epitaxial growth process.

In the illustrated embodiment, the first plasma etching gas includes carbon tetrafluoride (CF₄) supplied at a flow rate of 50 standard cubic centimeters per minute (SCCM) to 100 SCCM for 20 seconds to 40 seconds to remove portions of the protective silicon nitride layer 300. Additionally, the second plasma etching gas includes sulfur hexafluoride (SF₆) supplied at a flow rate of 5 SCCM to 20 SCCM, and the silicon substrate is etched in an etching chamber under a pressure of 40 mTorr to 60 mTorr, at an etching power of 200 W to 300 W and at a bias power of 0 W for 15 seconds to 25 seconds. Furthermore, the third plasma etching gas consists of SF₆ and a polymer gas formed by HBr and O₂, where HBr is supplied at a flow rate of 20 SCCM to 50 SCCM, O₂ is supplied at a flow rate of 2 SCCM to 10 SCCM, SF₆ is supplied at a flow rate of 5 SCCM to 10 SCCM, and the silicon substrate is etched in an etching chamber under a pressure of 5 mTorr to 10 mTorr, at an etching power of 100 W to 200 W and at a bias power of 200 W to 300 W for 10 seconds to 20 seconds.

In one embodiment, the plasma etching process is performed by sequentially introducing the first, second and third etching gases in a LAM Kiyo or kiyo45 etching tool.

As described herein, the Σ-shaped trench 400 is formed by using different plasma etching gases, among which, SF₆ has an isotropic characteristic and hence determines the width of the Σ-shaped trench 400, while HBr has an anisotropic characteristic and hence determines the depth of the Σ-shaped trench 400 together with SF₆. The profile of the Σ-shaped trench 400 being etched could be controlled by adjusting the flow rates and etching time of the respective plasma etching gases. The Σ-shaped trench 400 formed has an outer periphery closer to the conductive channel of the transistor and the Σ-shaped trench 400 is formed only by employing the plasma etching process whilst not employing the wet etching process, therefore, the wet etching process apparatuses are not needed, thus simplifying the process. In addition, a so-called sidewall spanning distance D (as shown in FIG. 7), defined as the maximum horizontal distance that the Σ-shaped trench 400 extends under a gate structure formed on one side thereof from a facing edge of a proximal gate protection layer (or sidewall) of the gate structure, and a vertical depth H (as shown in FIG. 7) of the Σ-shaped trench 400 can be individually controlled independently with respect to each other. In other words, the geometry of the Σ-shaped trench 500 is adjustable, which is advantageous to the widening of process window. In one specific embodiment, the vertical depth H of the Σ-shaped trench 400 is in the range of 400 Å to 600 Å, while the sidewall spanning distance D is in the range of 50 Å to 100 Å.

The preferred embodiments described herein are intended to explain aspects and features of the inventive technology in sufficient detail to enable those skilled in the art to understand and practice the technology, but not intended to limit the scope of the present invention in any way. Therefore, all modifications, substitutions and the like made without departing from the scope of the present invention are considered to be within the scope of the invention.

What is claimed is:

1. A method of forming a Σ-shaped trench, comprising the steps of:
providing a silicon substrate; and
performing a plasma etching process to form a Σ-shaped trench in the silicon substrate,
wherein the plasma etching process comprises:
etching the silicon substrate using a first plasma etching gas comprising a sulphur-containing fluoride; and
etching the silicon substrate using a second plasma etching gas comprising a sulphur-containing fluoride and a polymer gas.

2. The method of claim 1, wherein the first plasma etching gas comprises SF₆ supplied at a flow rate of 5 SCCM to 20 SCCM and the silicon substrate is etched using the first plasma etching gas in an etching chamber under a pressure of 40 mTorr to 60 mTorr, at an etching power of 200 W to 300 W and at a bias power of 0 W for 15 seconds to 25 seconds.

3. The method of claim 1, wherein the second plasma etching gas comprises SF₆ supplied at a flow rate of 5 SCCM to 10 SCCM and a polymer gas formed of HBr supplied at a flow rate of 20 SCCM to 50 SCCM and O₂ supplied at a flow rate of 2 SCCM to 10 SCCM; the silicon substrate is etched using the second plasma etching gas in an etching chamber under a pressure of 5 mTorr to 10 mTorr, at an etching power of 100 W to 200 W and at a bias power of 200 W to 300 W for 10 seconds to 20 seconds.

4. The method of claim 1, wherein the Σ-shaped trench has a horizontal width gradually increasing to a maximum and then gradually decreasing, from a surface of the silicon substrate downwards.

5. A method of forming a semiconductor device, comprising the steps of:
providing a silicon substrate having two gate structures formed thereon and forming a protective layer over the silicon substrate;
performing a plasma etching process on the protective layer and the underlying silicon substrate to form a Σ-shaped trench in a portion of the silicon substrate between the two gate structures; and
forming a SiGe epitaxial layer in the Σ-shaped trench;
wherein the plasma etching process comprises:
etching the protective layer to expose a surface of the silicon substrate using a first plasma etching gas comprising a carbon-containing fluoride;
etching the portion of the silicon substrate between the two gate structures using a second plasma etching gas comprising a sulphur-containing fluoride; and
etching the portion of the silicon substrate between the two gate structures using a third plasma etching gas comprising a sulphur-containing fluoride and a polymer gas.

6. The method of claim 5, wherein the protective layer is a silicon nitride layer and has a thickness of 100 Å to 150 Å.

7. The method of claim 6, wherein the first plasma etching gas comprises CF₄ supplied at a flow rate of 50 SCCM to 100 SCCM.

8. The method of claim 5, wherein the second plasma etching gas comprises SF₆ supplied at a flow rate of 5 SCCM to 20 SCCM and the silicon substrate is etched using the first plasma etching gas in an etching chamber under a pressure of 40 mTorr to 60 mTorr, at an etching power of 200 W to 300 W and at a bias power of 0 W for 15 seconds to 25 seconds.

9. The method of claim 5, wherein the third plasma etching gas comprises SF₆ supplied at a flow rate of 5 SCCM to 10 SCCM and a polymer gas formed of HBr and O₂; the silicon substrate is etched using the second plasma etching gas in an etching chamber under a pressure of 5 mTorr to 10 mTorr, at an etching power of 100 W to 200 W and at a bias power of 200 W to 300 W for 10 seconds to 20 seconds.

10. The method of claim 5, wherein the Σ-shaped trench has a horizontal width gradually increasing to a maximum and then gradually decreasing from a surface of the silicon substrate downwards.
